(19) United States
(12) Patent Application Publication
(10) Pub. No.: US 2025/0191915 A1
(43) Pub. Date: Jun. 12, 2025

(54) SEMICONDUCTOR THIN FILM COMPRISING INDIUM-SELENIDE COMPOUND, THIN FILM TRANSISTOR COMPRISING SAME AND METHOD OF MANUFACTURING FERROELECTRIC MEMORY COMPRISING SAME

(71) Applicant: POSTECH RESEARCH AND BUSINESS DEVELOPMENT FOUNDATION, Pohang-si (KR)

(72) Inventors: Yong-Young NOH, Pohang-si (KR); Jaeyun LEE, Pohang-si (KR)

(73) Assignee: POSTECH RESEARCH AND BUSINESS DEVELOPMENT FOUNDATION, Pohang-si (KR)

(21) Appl. No.: 18/943,178

(22) Filed: Nov. 11, 2024

(30) Foreign Application Priority Data
Dec. 8, 2023 (KR) 10-2023-0157351
Sep. 6, 2024 (KR) 10-2024-0135877

(51) Int. Cl. H01L 21/02; C23C 14/14; C23C 14/24; C23C 14/58; H01L 29/24; H01L 29/76; H01L 29/786

(52) U.S. Cl. CPC H01L 21/02631; C23C 14/14; C23C 14/24; C23C 14/5806; H01L 21/02568; H10D 30/6757; H10D 48/362; H10D 62/80

(57) ABSTRACT

Disclosed are semiconductor thin film comprising indium-selenide compound, thin film transistor comprising same and method of manufacturing ferroelectric memory comprising same. The method comprises (a) depositing at least one deposition source selected from the group consisting of indium, selenium and In₂Se₃ on a substrate by a thermal evaporation deposition method to form a coating layer; and (b) annealing the coating layer by heat treatment to manufacture a semiconductor thin film comprising an indium-selenide compound. The thin film transistor (TFT) manufactured based on an InₓSe_{y} channel layer using a deposition method of a thermal evaporation process according to the manufacturing method of the present disclosure has the effect of exhibiting excellent output/transfer characteristics and excellent electrical performance with high electron field effect mobility and a high on/off current ratio of 7×10⁸.

### CROSS REFERENCE TO RELATED APPLICATION

The present application claims priority to Korean Patent Applications No. 10-2023-0157351, filed Nov. 14, 2023, and 10-2024-0135877, filed Oct. 7, 2024, the entire contents of which are incorporated herein for all purposes by these references.

### BACKGROUND OF THE DISCLOSURE

### 1. Field of the Disclosure

The present disclosure relates to semiconductor thin film comprising indium-selenide compound, thin film transistor comprising same and method of manufacturing ferroelectric memory comprising same.

### 2. Description of the Related Art

Indium-based semiconductor thin films are being actively researched by applying cutting-edge technologies due to excellent electronic and optoelectronic properties. Among them, indium(III) selenide, which is coupled by the combination of III-VI, is a polymorphic material with multiple phases of α, β, γ, δ, and κ, and it is known to have one layer of two-dimensional structure with five atom folds of Se—In—Se—In—Se atomic composition. Different phases exhibit different physical properties. The indium(III) selenide of a phase has a non-central radial symmetry structure. when an electric field is applied from the outside. Polarization is formed by the movement of Se atoms in the middle, which is maintained even when the electric field is not applied, so it is a ferroelectric. On the other hand, the indium(IE) selenide of β phase has a central radial symmetrical structure, so it does not exhibit ferroelectric properties.

Based on these properties, indium(III) selenide semiconductor thin films have the potential to be applied in a variety of fields, comprising metal oxide semiconductor field-effect transistors (MOSFETs), photodetectors, solar cells, nonvolatile memories, and ferroelectric semiconductor field-effect transistors (FeS-FETs).

Nevertheless, the methods for forming indium(IE) selenide semiconductor thin films, such as chemical vapor deposition (CVD) and mechanical exfoliation, are currently limited to a maximum lateral size of 1 to 2 centimeters. In addition, field-effect transistors as basic semiconductor devices with excellent performance have been rarely reported, and even if they have high electron field-effect mobility, they exhibit low on/off current ratios (˜10³).

Therefore, in the development of advanced devices using indium(III) selenide semiconductor thin films, the development of large-area synthesis methods is necessary in addition to the development of high-performance transistors.

### SUMMARY OF THE DISCLOSURE

The purpose of the present disclosure is to solve the above problems, and to provide a high-performance n-channel transistor using indium-selenide as a semiconductor thin film using a thermal evaporation deposition technique, and at the same time to provide a thin film transistor with a large area and high reproducibility.

The other purpose of the present disclosure is to provide InₓSe_{y}, an n-type semiconductor having a new combination of In and Se, using a thermal evaporation deposition technique.

One aspect of the present disclosure provides a method of manufacturing a semiconductor thin film, the method comprising: (a) depositing at least one deposition source selected from the group consisting of indium, selenium and In₂Se₃ on a substrate by a thermal evaporation deposition method, thus forming a coating layer; and (b) annealing the coating layer by heat treatment, thus manufacturing a semiconductor thin film comprising an indium-selenide compound represented by Chemical Formula 1.

InₓSe_{y} [Chemical Formula 1]

in Chemical Formula 1, x is 0<x≤3, and y is 0<y≤4.

In addition, the compound of Chemical Formula 1 may comprise the compound represented by In₂Se₃.

In addition, the indium-selenide compound may comprise the indium-selenide compound of kappa(κ) phase.

In addition, the semiconductor thin film may have ferroelectricity or paraelectricity.

In addition, the ferroelectricity or the paraelectricity of the semiconductor thin film may be regulated by controlling a rate of the depositing in the step (a).

In addition, the semiconductor thin film may be converted from paraelectricity to ferroelectricity by increasing a rate of the depositing in the step (a).

In addition, a rate of the depositing in the step (a) may be 0.1 to 3.4 Ås⁻¹.

In addition, the ferroelectricity or paraelectricity of the semiconductor thin film may be regulated by controlling a thickness of the coating layer of the step (a).

In addition, the semiconductor thin film may be converted from paraelectricity to ferroelectricity by increasing the thickness of the coating layer of the step (a).

In addition, the thickness of the semiconductor thin film of the step (b) may be 5 to 50 nm.

In addition, the semiconductor thin film having the indium-selenide compound of kappa(κ) phase may be manufactured by annealing the coating layer of the step (b).

In addition, the annealing of the coating layer of the step (b) may be carried out for 0.1 to 5 hours.

In addition, the annealing of the coating layer of the step (b) may be carried out at the range of 200 to 400° C.

Another aspect of the present disclosure provides a semiconductor thin film comprising an indium-selenide compound of a kappa(κ) phase and represented by Chemical Formula 1.

InₓSe_{y} [Chemical Formula 1]

in Chemical Formula 1, x is 0<x≤3, and y is 0<y≤4.

In addition, the semiconductor thin film may have a band gap of 1.0 to 2.0 eV.

In addition, the semiconductor thin film may have an on/off current ratio of 1×10⁶ or more and an electron mobility of 10 cm²/Vs or more.

In addition, in the semiconductor thin film, five atoms may form one layer in the order of Se—In—Se—In—Se.

In addition, the semiconductor thin film may be used for any one n-channel selected from the group consisting of a thin film transistor, a memory device, a solar cell, a light emitting diode, a photodiode, and a photo sensor.

The other aspect of the present disclosure provides a thin film transistor (10), which comprises a gate electrode (100); an insulating layer (200) located on the gate electrode; a semiconductor thin film (300) located on the insulating layer and comprising an indium-selenide compound represented by Chemical Formula 1; and a source electrode (400) and a drain electrode (500) located at a distance from each other on the semiconductor thin film.

InₓSe_{y} [Chemical Formula 1]

in Chemical Formula 1, x is 0<x≤3, and y is 0<y≤4.

In addition, the semiconductor thin film may comprise indium-selenide of kappa phase.

In addition, the gate electrode may comprise at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide and poly(3,4-ethylenedioxythiophene) polystyrene sulfonate (PEDOT:PSS).

A thin film transistor (TFT) fabricated based on the InₓSe_{y} channel layer according to the present disclosure exhibits excellent output/transfer characteristics and superior electrical performance with high electron field-effect mobility and a high on/off current ratio of ˜10⁸.

### BRIEF DESCRIPTION OF THE DRAWINGS

Since the accompanying drawings are for reference in describing exemplary Examples of the present disclosure, the technical spirit of the present should not be construed as being limited to the accompanying drawings, in which:

FIG. 1A shows a thin film transistor according to an embodiment of the present disclosure.

FIG. 1B shows the output characteristics of the TFT according to Example 1-3.

FIG. 1C shows the transfer characteristics of the TFT according to Example 1-3.

FIG. 2A shows the transfer characteristics of the TFT of Example 1-1, which carried out the post-processing process of annealing for 0.5 hours.

FIG. 2B shows the transfer characteristics of the TFT of Example 1-2, which carried out the post-processing process of annealing for 1 hour.

FIG. 2C shows the transfer characteristics of the TFT of Example 1-3, which carried out the post-processing process of annealing for 4 hours.

FIG. 2D shows the change in electron mobility according to the change in the post-processing process of annealing time.

FIGS. 2E to 2G show the output curves according to the change in the deposition thickness in Example 1.

FIG. 3A shows the form of the thin film in which a 40 nm semiconductor thin film was deposited in Example 2-3.

FIGS. 3B and 3C show graphs measuring ferroelectricity of an 11 nm thin film of Example 2-1 using PFM equipment.

FIGS. 3D and 3E show graphs measuring ferroelectricity of a 40 nm thin film having the surface of FIG. 3A using PFM equipment.

FIG. 4 shows an XRD graph of an InₓSe_{y} semiconductor thin film obtained during the manufacturing process of a TFT according to Example 1.

FIG. 5 shows a Raman spectroscopy result of an InₓSe_{y} semiconductor thin film obtained during the manufacturing process of a TFT according to Example 1.

FIG. 6 shows an XPS result of an InₓSe_{y} semiconductor thin film obtained during the manufacturing process of a TFT according to Example 1.

FIG. 7 shows a TEM result of an InₓSe_{y} semiconductor thin film obtained during the manufacturing process of a TFT according to Example 1.

FIG. 8 shows a UV-vis spectroscopy result showing the energy band gap of kappa phase In₂Se₃.

FIG. 9 shows a result of evaporation rate variation during the manufacturing of a semiconductor thin film in a thin film transistor of the present disclosure.

FIG. 10 shows a diagram showing Wafer-scale statistics & Benchmark and a 4-inch wafer.

### DESCRIPTION OF THE PREFERRED EMBODIMENTS

Herein after, examples of the present disclosure will be described in detail with reference to the accompanying drawings in such a manner that the ordinarily skilled in the art can easily implement the present disclosure.

The description given below is not intended to limit the present disclosure to specific Examples. In relation to describing the present disclosure, when the detailed description of the relevant known technology is determined to unnecessarily obscure the gist of the present disclosure, the detailed description may be omitted.

The terminology used herein is for the purpose of describing particular examples only and is not intended to limit the scope of the present disclosure. As used herein, the singular forms “a”, “an”, and “the” are intended to comprise the plural forms as well unless the context clearly indicates otherwise. It will be further understood that the terms “comprise” or “have” when used in the present disclosure specify the presence of stated features, integers, steps, operations, elements and/or combinations thereof, but do not preclude the presence or addition of one or more other features, integers, steps, operations, elements, and/or combinations thereof.

Terms comprising ordinal numbers used in the specification, “first”, “second”, etc. may be used to discriminate one component from another component, but the order or priority of the components is not limited by the terms unless specifically stated. These terms are used only for the purpose of distinguishing a component from another component. For example, without departing from the scope of the present disclosure, a first component may be referred as a second component, and a second component may be also referred to as a first component.

In addition, when it is mentioned that a component is “formed” or “stacked” on another component, it should be understood such that one component may be directly attached to or directly stacked on the front surface or one surface of the other component, or an additional component may be disposed between them.

Hereinafter, the embodiment of the present disclosure shall be explained with reference to the attached drawing, and in describing it by reference to the accompanying drawing, the same or corresponding components shall be given the same FIG. number and the duplicate description thereof shall be omitted.

Hereinafter, a semiconductor thin film comprising an indium-selenide compound of the present disclosure, a thin film transistor comprising the same, and a method for manufacturing a ferroelectric memory will be described in detail. However, this is presented as an example, and the present disclosure is not limited thereby, and the present disclosure is defined only by the scope of the claims to be described later.

The present disclosure provides a method of manufacturing a semiconductor thin film, the method comprising: (a) depositing at least one deposition source selected from the group consisting of indium, selenium and In₂Se₃ on a substrate by a thermal evaporation deposition method to form a coating layer; and (b) annealing the coating layer by heat treatment to manufacture a semiconductor thin film comprising an indium-selenide compound represented by Chemical Formula 1.

InₓSe_{y} [Chemical Formula 1]

in Chemical Formula 1, x is 0<x≤3, and y is 0<y≤4.

In the case of using a conventional chemical vapor deposition method, there is a problem that the film size is optimized only to 1×1 cm² and cannot be expanded to a large area. In the case of using a thermal evaporation deposition method like the present disclosure, it may be expanded to a wafer scale.

In addition, the thermal evaporation may be carried out at a pressure of 10⁻³ Torr or less. When the thermal evaporation exceeds a pressure of 10⁻³ Torr, it may contain impurities, which is undesirable.

In addition, the heat treatment may be carried out at a temperature of 200 to 400° C. When the heat treatment is carried out at a temperature of less than 200° C., sufficient heat energy to cause a change in the composition of the thin film is not supplied, which is undesirable. When the temperature exceeds 400° C., the physical properties of the thin film change, which is undesirable.

In addition, the compound of Chemical Formula 1 may comprise the compound represented by In₂Se₃.

In addition, the indium-selenide compound may comprise the indium-selenide compound of kappa phase.

In addition, the semiconductor thin film may have ferroelectricity or paraelectricity.

In addition, the ferroelectricity or paraelectricity of the semiconductor thin film may be regulated by controlling a rate the depositing in the step (a).

In addition, the semiconductor thin film may be converted from paraelectricity to ferroelectricity by increasing a rate of the depositing in the step (a).

In addition, a rate of the depositing in the step (a) may be 0.1 to 3.4 Å s⁻¹ and preferably 0.2 to 1 Å s⁻¹. When the deposition rate is less than 0.1 Å/s, the process time taken for thin film deposition is too long, which is undesirable. When it exceeds 3.4 Å/s, the surface roughness of the thin film increases, which is undesirable.

In addition, the ferroelectricity or paraelectricity of the semiconductor thin film may be regulated by controlling a thickness of the coating layer of the step (a).

In addition, the semiconductor thin film may be converted from paraelectricity to ferroelectricity by increasing a thickness of the coating layer of the step (a).

In addition, the thickness of the semiconductor thin film of the step (b) may be 5 to 50 nm. When the thickness of the semiconductor thin film is less than 5 nm, the charge transfer channel is not properly formed, which is undesirable. When it exceeds 50 nm, the electron density is very high, which increases collisions between electrons and collisions between electrons and impurities, which is undesirable because the performance of the transistor deteriorates.

In addition, the semiconductor thin film comprising an indium-selenide compound of a kappa phase may be manufactured by annealing the coating layer of the step (b).

In addition, the annealing of the coating layer of the step (b) may be carried out for 0.1 to 5 hours. When the annealing is carried out for less than 0.1 hour, the channel region through which charges can move is not activated, which is undesirable. When it exceeds 5 hours, it may cause excessive growth of the crystal grain size, which is undesirable.

In addition, the annealing of the coating layer of the step (b) may be carried out at 200 to 400° C., and preferably at 250° C. Here, when the annealing temperature is less than 200° C., the annealing effect is not present, which is undesirable. When it exceeds 400° C., the properties of the thin film are deformed, which is undesirable.

In addition, the annealing may be carried out in an atmosphere of an inert gas. The inert gas may comprise at least one selected from the group consisting of helium, neon, argon, and nitrogen.

Another aspect of the present disclosure provides a semiconductor thin film comprising an indium-selenide compound having a kappa phase and represented by Chemical Formula 1.

InₓSe_{y} [Chemical Formula 1]

in Chemical Formula 1, x is 0<x≤3, and y is 0<y≤4.

In addition, the semiconductor thin film may comprise indium-selenide of α phase.

In addition, the semiconductor thin film may comprise indium-selenide of β phase.

In addition, the semiconductor thin film may comprise indium-selenide of γ phase.

In addition, the semiconductor thin film may have a band gap of 1.0 to 2.0 eV. When the band gap is less than 1.0 eV, the current may not be properly cut off in the off state in which the transistor should be turned off. So it is difficult to control the transistor, which is undesirable. When the band gap exceeds 2.0 eV, the charge carriers may be difficult to be generated and the current may be reduced in the on state in which the transistor is turned on. So and the performance of the transistor may be deteriorated, which is undesirable.

In addition, the semiconductor thin film may have an on/off current ratio of 1×10⁶ or more and preferably 1×10⁸ to 9×10⁸, and an electron mobility of 10 cm²/Vs or more and preferably 10 to 50 cm²/Vs. When the on/off current ratio is less than 1×10⁶, it is undesirable because signal processing errors may occur as it becomes difficult to clearly distinguish 0 and 1 in the digital circuit. When the electron mobility is less than 10 cm²/Vs, the current driving capability of the transistor may be reduced, which may slow down the switching rate, which is undesirable.

In addition, the semiconductor thin film may have a layered structure with two-dimension.

In addition, in the semiconductor thin film, five atoms may form one layer in the sequence of Se—In—Se—In—Se.

In addition, the semiconductor thin film may be used for any one n-channel selected from the group consisting of a thin film transistor, a memory device, a solar cell, a light emitting diode, a photodiode, and a photo sensor.

Another aspect of the present disclosure provides a thin film transistor (10), which comprises a gate electrode (100); an insulating layer (200) located on the gate electrode; a semiconductor thin film (300) located on the insulating layer and comprising an indium-selenide compound represented by Chemical Formula 1; and a source electrode (400) and a drain electrode (500) located at a distance from each other on the semiconductor thin film.

InₓSe_{y} [Chemical Formula 1]

in Chemical Formula 1, x is 0<x≤3, and y is 0<y≤4.

In addition, the semiconductor thin film may comprise indium-selenide of a kappa phase.

In addition, the gate electrode may comprise at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide, and poly(3,4-ethylenedioxythiophene) polystyrene sulfonate (PEDOT:PSS).

In addition, the source electrode and the drain electrode may each comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide, and poly(3,4-ethylenedioxythiophene) polystyrene sulfonate (PEDOT:PSS).

In addition, the insulating layer may comprise at least one selected from the group consisting of silicon dioxide, glass, quartz, alumina, silicon carbide, magnesium oxide, polyethylene naphthalate (PEN), polyethylene terephthalate (PET), polystyrene (PS), polyimide (PI), polyvinyl chloride (PVC), polyvinyl pyrrolidone (PVP), polyethylene (PE), silicon oxide (SiO₂), germanium, polyvinyl alcohol (PVA), polymethyl methacrylate (PMMA), zirconium oxide (ZrO₂), aluminum oxide (AlO₂), and hafnium oxide (HfO₂).

The other aspect of the present disclosure provides a memory device comprising a semiconductor thin film, wherein the semiconductor thin film has a kappa phase and comprises an indium-selenide compound represented by Chemical Formula 1.

InₓSe_{y} [Chemical Formula 1]

in Chemical Formula 1, x is 0<x≤3, and y is 0<y≤4.

### EXAMPLES

Hereinafter, the examples of the present disclosure will be described. However, the examples are for illustrative purposes, and the scope of the present disclosure is not limited by the examples.

### Example: Fabrication of n-Channel Thin Film Transistor Using Thermal Evaporation Deposition Process

### Example 1: Annealing Time Variation

### Example 1-1: 0.5 Hour Annealing and 11 nm Semiconductor Thin Film Thickness

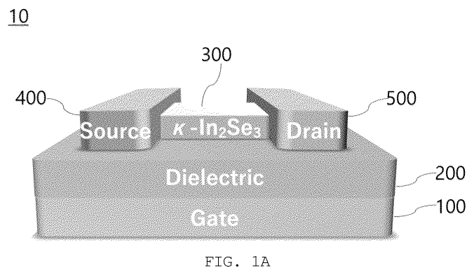

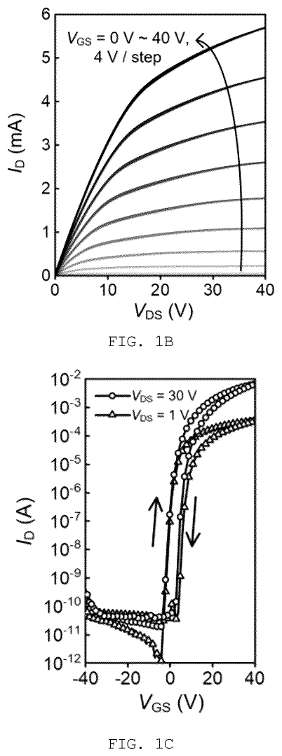

FIG. 1A shows a thin film transistor according to an embodiment of the present disclosure.

Referring to FIG. 1A, to deposit InₓSe_{y}-based semiconductor films, commercially available In₂Se₃ powder (purity of 99% or higher) was used as an evaporation source. The film was deposited using a conventional thermal evaporator. The temperature of substrate was 25° C., and the vacuum pressure before evaporation was below 10⁻³ Torr. The distance between the substrate and the boat loaded with In₂Se₃ was 2-50 cm. The deposition rate was 0.2 Å s⁻¹. The thickness of the InₓSe_{y} film was monitored during the deposition and was found to be 11 nm. The deposited sample was first annealed at 250° C. for 0.5 h in a N₂-filled glove box to form an In₂Se₃ semiconductor thin film. Afterwards, a thin film transistor (TFT) was fabricated by thermal deposition of Au with a source/drain electrode, respectively.

### Example 1-2: 1 Hour Annealing

A thin film transistor (TFT) was manufactured in the same manner as in Example 1-1, except that annealing was carried out for 1 hour instead of 0.5 hour in Example 1-1.

### Example 1-3: 4 Hour Annealing

A thin film transistor (TFT) was manufactured in the same manner as in Example 1-1, except that annealing was carried out for 4 hours instead of 0.5 hour in Example 1-1.

### Example 2: Change in Semiconductor Thin Film Thickness

### Example 2-1: 11 nm Semiconductor Thin Film Thickness

To deposit InₓSe_{y}-based semiconductor film, commercially available In₂Se₃ powder (purity of 99% or higher) was used as an evaporation source. The film was deposited using a conventional thermal evaporator. The temperature of substrate was 25° C., and the vacuum pressure before evaporation was below 10⁻³ Torr. The distance between the substrate and the boat loaded with In₂Se₃ was 2-50 cm. The deposition rate was 0.2 Å s⁻¹. The thickness of the InₓSe_{y} film was monitored during the deposition and was found to be 11 nm. The deposited sample was first annealed at 250° C. for 4 h in a N₂-filled glove box to form an In₂Se₃ semiconductor thin film. Afterwards, a thin film transistor (TFT) was fabricated by thermal deposition of Au with a source/drain electrode, respectively.

### Example 2-2: 20 nm Semiconductor Thin Film Thickness

A thin film transistor (TFT) was manufactured in the same manner as in Example 2-1, except that the semiconductor thin film thickness was formed to 20 nm instead of 11 nm in Example 2-1.

### Example 2-3: 40 nm Semiconductor Thin Film Thickness

A thin film transistor (TFT) was manufactured in the same manner as in Example 2-1, except that the semiconductor thin film thickness was formed to 40 nm instead of 11 nm in Example 2-1.

### Example 3: Change in Deposition Rate

### Example 3-1: Deposition Rate 0.2 Å s⁻¹

To deposit InₓSe_{y}-based semiconductor films, commercially available In₂Se₃ powder (purity 99% or higher) was used as an evaporation source. The films were deposited using a conventional thermal evaporator. The substrate temperature was 25° C., and the vacuum pressure before evaporation was below 10⁻³ Torr. The distance between the substrate and the boat loaded with In₂Se₃ was 2-50 cm. The deposition rate was 0.2 Å s⁻¹. The thickness of the InₓSe_{y} film was monitored during the deposition and was found to be 11 nm. The deposited sample was first annealed at 250° C. for 4 h in a N₂-filled glove box to form an In₂Se₃ semiconductor thin film. Afterwards, a thin film transistor (TFT) was fabricated by thermal deposition of Au with a source/drain electrode, respectively.

### Example 3-2: Deposition Rate 0.8 Å s⁻¹

A thin film transistor (TFT) was manufactured in the same manner as in Example 3-1, except that the deposition rate was 0.8 Å s⁻¹ instead of 0.2 Å s⁻¹ in Example 3-1.

### Example 3-3: Deposition Rate 2.0 Å s⁻¹

A thin film transistor (TFT) was manufactured in the same manner as in Example 3-1, except that the deposition rate was 2.0 Å s⁻¹ instead of 0.2 Å s⁻¹ in Example 3-1.

### Comparative Example 1: Deposition Rate 3.5 Å s⁻¹

A thin film transistor (TFT) was manufactured in the same manner as in Example 3-1, except that the deposition rate was 3.5 Å s⁻¹ instead of 0.2 Å s⁻¹ in Example 3-1.

### Experimental Example

### Experimental Example 1: Output and Transfer Characteristics of Transistor

FIG. 1B shows the output characteristics of the TFT according to Example 1-3, and FIG. 1C shows the transfer characteristics of the TFT according to Example 1-3.

Referring to FIGS. 1B and 1C, the TFT manufactured on the basis of InₓSe_{y} semiconductor thin film shows typical n-type transistor characteristics, and exhibits excellent output/transfer characteristics and excellent electrical performance with a high electron field effect mobility of 37 cm²/V·s and a high on/off current ratio of 7×10⁸.

TABLE 1

| | Annealing | Semiconductor | Deposition | Electron | | Memory |
|---|---|---|---|---|---|---|
| | time | thin film | rate | mobility | | gap |
| | (hr) | thickness (nm) | (Å s⁻¹) | (cm²/Vs) | Iₒₙ/I_{off} | (V) |
| Example 1-1 | 0.5 | 11 | 0.2 | 15 | 2 × 10⁸ | 12 |
| Example 1-2 | 1 | 11 | 0.2 | 23 | 4 × 10⁸ | 9 |
| Example 1-3 | 4 | 11 | 0.2 | 37 | 7 × 10⁸ | 8 |
| Example 2-1 | 4 | 11 | 0.2 | 37 | 7 × 10⁸ | 8 |
| Example 2-2 | 4 | 20 | 0.2 | 14.2 | 5 × 10⁸ | 17 |
| Example 2-3 | 4 | 40 | 0.2 | 10.9 | 4 × 10⁸ | 35 |
| Example 3-1 | 4 | 11 | 0.2 | 37 | 7 × 10⁸ | 8 |
| Example 3-2 | 4 | 11 | 0.8 | 11.8 | 5 × 10⁷ | 12 |
| Example 3-3 | 4 | 11 | 2.0 | 0.008 | 7 × 10⁴ | 20 |
| comparative | 4 | 11 | 3.5 | 0 | — | — |
| example 1 | | | | | | |

### Experimental Example 2: Transistor Characteristics

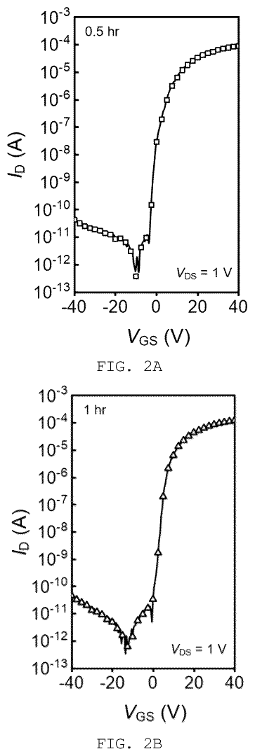

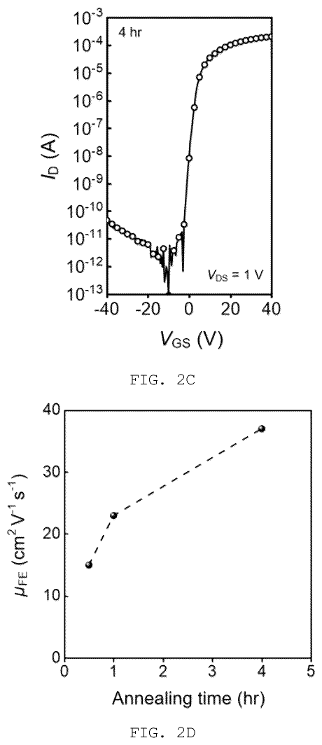

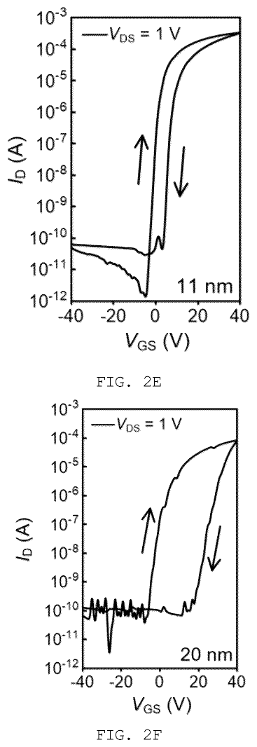

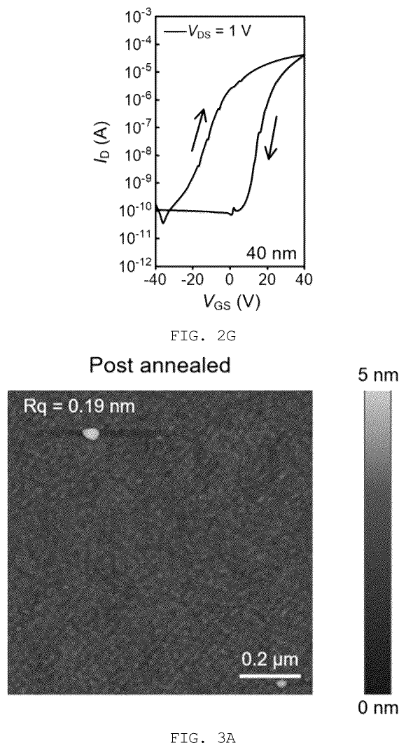

According to Post-Treatment Annealing Process Time and Thickness FIGS. 2A to 2C show output curves according to the changes in the post-processing annealing time in Example 1, FIG. 2D shows changes in electron mobility according to the post-processing annealing time, and FIGS. 2E to 2G show output curves according to changes in the deposition thickness in Example 1.

Referring to FIGS. 2A to 2G, when the annealing process time increases from 30 minutes to 4 hours, it can be confirmed that the mobility improves from 15 cm²/Vs to 37 cm²/Vs as the on-current and transconductance increase, and the hysteresis characteristics are significantly reduced. In addition, it can be confirmed that the hysteresis characteristics increase as the thickness of the semiconductor thin film increases from 11 nm to 40 nm. Also the memory gap (Memory Window), which is a basic characteristic as a memory device, shows a level of 8 V in a transistor using an 11 nm semiconductor thin film, and when it increases to 40 nm, it increases significantly to a level of 35 V, confirming that the ferroelectricity is proportional to the thickness of the semiconductor thin film. Through this, it was confirmed that the device using the indium selenide thin film shows the possibility of not only a transistor but also a nonvolatile memory.

### Experimental Example 3: Thin Film Characteristics and Ferroelectricity of Semiconductor Film

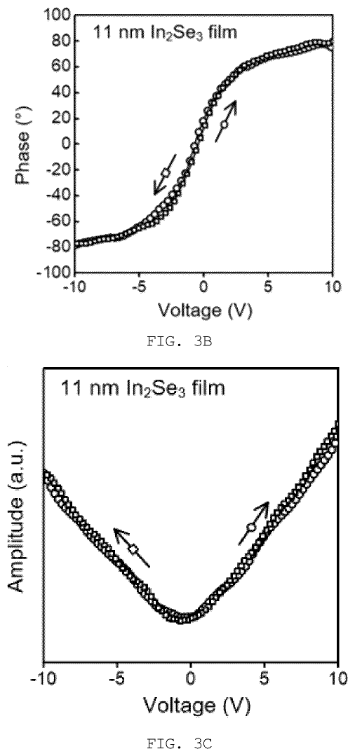

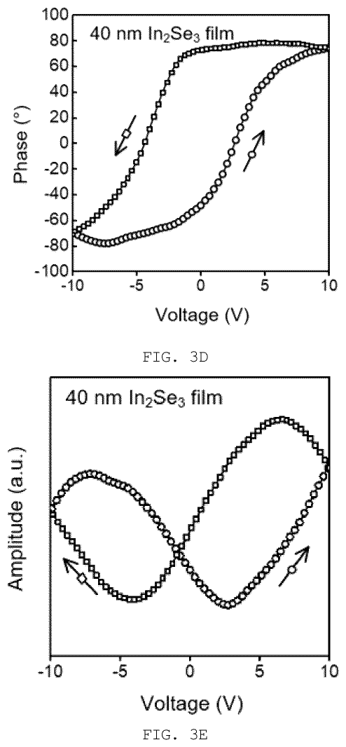

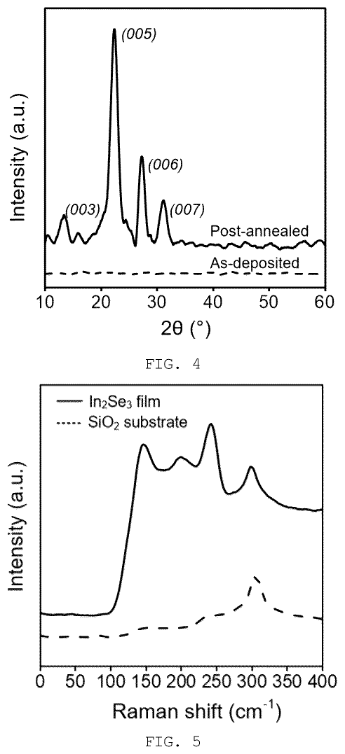

FIG. 3A shows the form of a thin film in which a 40 nm semiconductor thin film was deposited in Example 2-3, and FIGS. 3B and 3C show graphs showing the ferroelectricity of an 11 nm thin film of Example 2-1 using PFM equipment, and FIGS. 3D and 3E show graphs showing the ferroelectricity of a 40 nm thin film having the surface of FIG. 3A using PFM equipment.

Referring to FIGS. 3A to 3C, when the surface of the thin film was measured with a size of 10 μm×10 μm using PFM (Piezoresponse Force Microscopy) equipment, it can be seen that the thin film has low surface roughness, showing a square mean height of 0.0019 μm. When the gate voltage is applied in the order of 0 V->+10 V->-10 V->+10 V, the volume change (Amplitude) according to the presence or absence of polarity is examined. Since it exhibits hysteresis characteristics and symmetry, it can be confirmed that it is a ferroelectric thin film.

In addition, the method by which ferroelectric memory properties and non-ferroelectric properties can be achieved at the same time can be obtained by adjusting the thickness. FIGS. 3B and 3C show that the transistor device of 11 nm can be applied as a logic orientation because the hysteresis phenomenon cannot be observed as a result of PFM measurement in an 11 nm thin film, and the transistor device of 40 nm can be applied as a ferroelectric memory orientation because the PFM measurement result in the 3D and 3E of 40 nm shows a clear hysteresis phenomenon.

### Experimental Example 4: Phase Determination Experiment of In₂Se₃

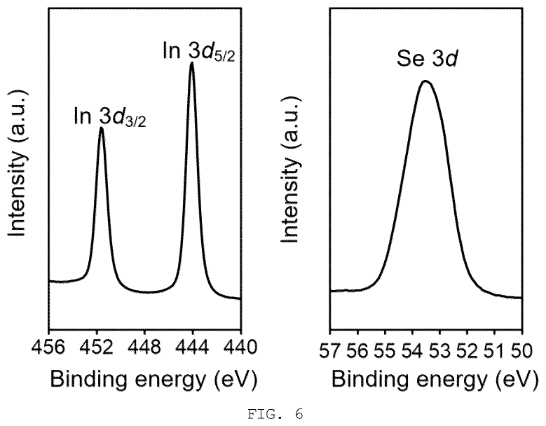

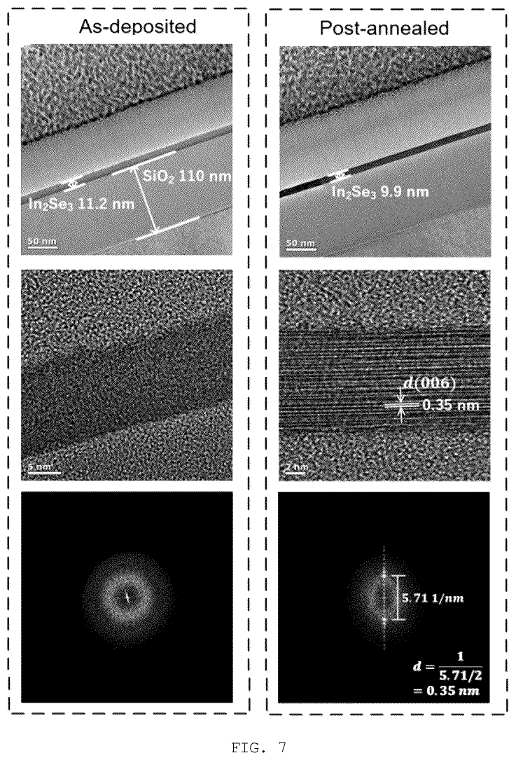

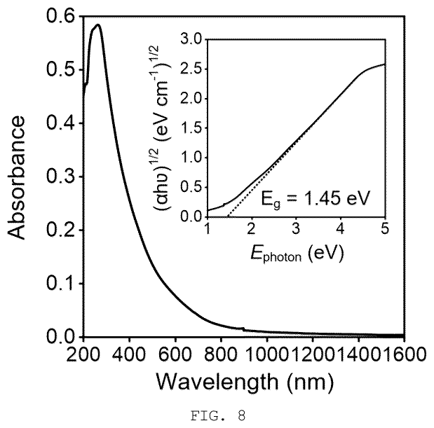

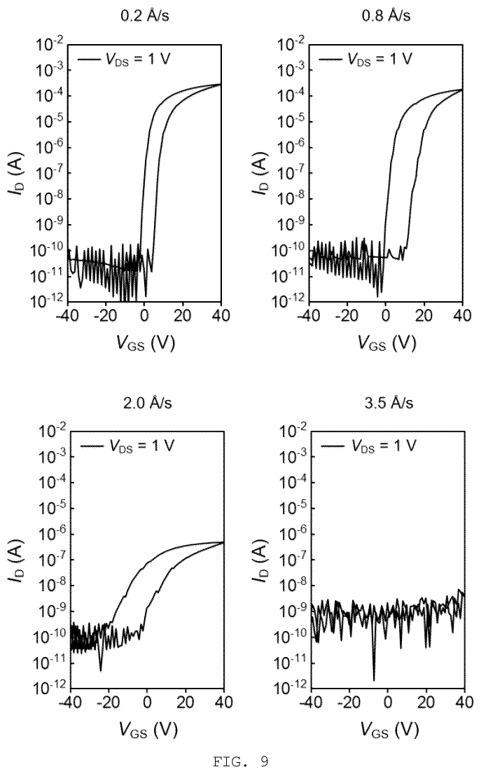

FIG. 4 shows an XRD graph for an InₓSe_{y} semiconductor thin film obtained during the TFT manufacturing process according to Example 1, FIG. 5 shows a Raman spectroscopy result for an InₓSe_{y} semiconductor thin film obtained during the TFT manufacturing process according to Example 1, FIG. 6 shows an XPS result for an InₓSe_{y} semiconductor thin film obtained during the TFT manufacturing process according to Example 1, and FIG. 7 shows a TEM result for an InₓSe_{y} semiconductor thin film obtained during the TFT manufacturing process according to Example 1.

FIGS. 4 to 7 show experimental results for determining the phase of In₂Se₃.

Referring to FIG. 4, the crystal structure of the thin film is shown, it was confirmed that only the (003), (005), (006), and (007) peaks along the z-axis of the thin film are characteristically shown, and it was confirmed that this characteristic is identical to the characteristic of kappa phase In₂Se₃.

Referring to FIG. 5, the Raman spectroscopy results showing the phonon scattering of atoms in the thin film showed completely different characteristics from the well-known alpha, beta, and gamma phases, and it was confirmed that this result also corresponds to the kappa phase.

Referring to FIG. 6, the XPS results showing the chemical element state in the thin film confirmed the bonding of the 3d orbital of In and the 3d orbital of Se in the kappa phase.

Referring to FIG. 7, the In₂Se₃ thin film deposited was heat treated by TEM, and a horizontal rearrangement of atoms occurred in the amorphous thin film, and a thin film with a distinct two-dimensional shape was formed. It was confirmed that the 0.35 nm gap in the FIG. 7 is the same as the (006) arrangement of the kappa phase In₂Se₃. The kappa phase In₂Se₃ confirmed in this way is a phase that has never been applied to electronic devices, unlike the well-known a, R, and y phases, and thus it has application value as a new material.

### Experimental Example 5: Confirmation of Energy Band Gap of Kappa Phase In₂Se₃

FIG. 8 shows the result of UV-vis spectroscopy showing the energy band gap of In₂Se₃ of kappa phase.

Referring to FIG. 8, the energy band gap of kappa phase In₂Se₃ obtained additionally using UV-vis spectroscopy was 1.45 eV, confirming that it has the characteristics of a semiconductor. Through this, it was confirmed that the transistor device can be operated.

### Experimental Example 6: Evaporation Rate Variation Experiment

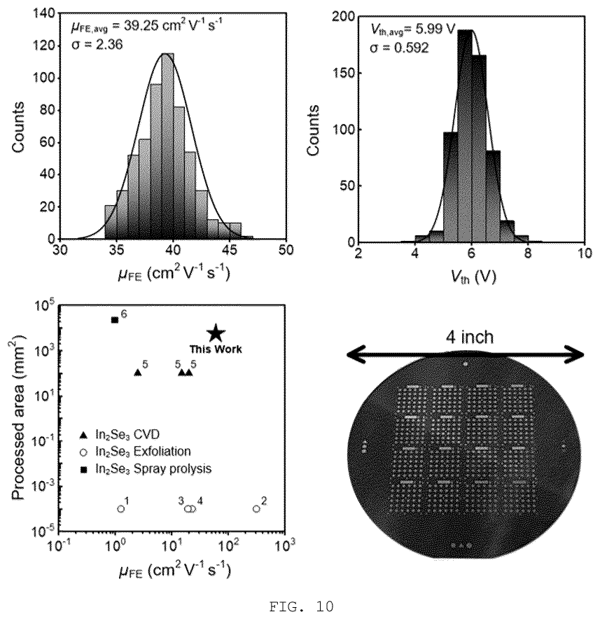

FIG. 9 shows the result of evaporation rate variation in the manufacture of a semiconductor thin film in the thin film transistor of the present disclosure. Referring to FIG. 9, it was confirmed that the deposition rate should be additionally controlled in the method of controlling the thickness in the method of manufacturing a semiconductor thin film in a thin film transistor. The experimental results confirmed that when the deposition rate is slowed down, the characteristics of a device with a small hysteresis phenomenon can be obtained, and when the deposition rate is increased, the hysteresis phenomenon increases. However, it was confirmed that the device performance is greatly degraded when the deposition rate is 3.5 Å/s or higher.

### Experimental Example 7: Wafer-Scale Statistics & Benchmark

FIG. 10 shows a diagram showing wafer-scale statistics & benchmark and a 4-inch wafer.

Referring to FIG. 10, In₂Se₃ as a two-dimensional semiconductor material has a clear limit to large-area scaling regardless of phase. This limit can be overcome through a large-area scaling experiment using a thin film process of thermal evaporation, and as a result of conducting the process using a 4-inch wafer containing 24×24 transistor devices, a charge mobility with a standard deviation of 2.36 (average=39.25 cm² V⁻¹ s⁻¹) and a threshold voltage with a standard deviation of 0.592 (average=5.99 V) was obtained. These results of the present invention for In₂Se₃ transistor confirmed the most well-balanced results in terms of charge mobility and large-area scaling among the In₂Se₃ transistors developed to date.

References 1 to 6 used in FIG. 10 are described. In FIG. 10, 1 is ACS Appl. Mater. Interfaces 2018, 10, 27584-27588, 2 is Nature Electronics volume 2, pages 580-586 (2019), 3 is Micromachines 2022, 13(6), 956, 4 is ACS Appl. Mater. Interfaces 2022, 14, 23637-23644, 5 is Nature Nanotechnology volume 18, pages 55-63 (2023), 6. Adv. Mater. 2024, 36, 2308301.

The scope of the present disclosure is defined by the following claims rather than the above detailed description, and all changes or modifications derived from the meaning and scope of the claims and their equivalent concepts should be interpreted as falling into the scope of the present disclosure.

What is claimed is:

1. A method of manufacturing a semiconductor thin film, the method comprising:
(a) depositing at least one deposition source selected from the group consisting of indium, selenium and In₂Se₃ on a substrate by a thermal evaporation deposition method, thus forming a coating layer; and
(b) annealing the coating layer by heat treatment, thus manufacturing a semiconductor thin film comprising an indium-selenide compound represented by Chemical Formula 1.
InₓSe_{y} [Chemical Formula 1]
in Chemical Formula 1, x is 0<x≤3, and y is 0<y≤4.

2. The method of claim 1, wherein the compound of Chemical Formula 1 comprises the compound represented by In₂Se₃.

3. The method of claim 1, wherein the indium-selenide compound comprises the indium-selenide compound of kappa(κ) phase.

4. The method of claim 1, wherein the semiconductor thin film has ferroelectricity or paraelectricity.

5. The method of claim 1, wherein the ferroelectricity or the paraelectricity of the semiconductor thin film is regulated by controlling a rate of the depositing in the step (a).

6. The method of claim 1, wherein the semiconductor thin film is converted from paraelectricity to ferroelectricity by increasing a rate of the depositing in the step (a).

7. The method of claim 1, wherein a rate of the depositing in the step (a) is 0.1 to 3.4 Å s⁻¹.

8. The method of claim 1, wherein the ferroelectricity or paraelectricity of the semiconductor thin film is regulated by controlling a thickness of the coating layer of the step (a).

9. The method of claim 1, wherein the semiconductor thin film is converted from paraelectricity to ferroelectricity by increasing a thickness of the coating layer of the step (a).

10. The method of claim 1, wherein the thickness of the semiconductor thin film of the step (b) is 5 to 50 nm.

11. The method of claim 1, wherein the semiconductor thin film comprising the indium-selenide compound of kappa(κ) phase is manufactured by annealing the coating layer of the step (b).

12. The method of claim 1, wherein the annealing of the coating layer of the step (b) is carried out at the range of 200 to 400° C.

13. A semiconductor thin film, the semiconductor thin film comprising an indium-selenide compound of kappa(κ) phase represented by Chemical Formula 1:
InₓSe_{y} [Chemical Formula 1]
in Chemical Formula 1, x is 0<x≤3, and y is 0<y≤4.

14. The semiconductor thin film of claim 13, wherein the semiconductor thin film has a band gap of 1.0 to 2.0 eV.

15. The semiconductor thin film of claim 13, wherein the semiconductor thin film has an on/off current ratio of 1×10⁶ or more and an electron mobility of 10 cm²/Vs or more.

16. The semiconductor thin film of claim 13, wherein in the semiconductor thin film, five atoms form one layer in the sequence of Se—In—Se—In—Se.

17. The semiconductor thin film of claim 13, wherein the semiconductor thin film is used for any one n-channel selected from the group consisting of a thin film transistor, a memory device, a solar cell, a light emitting diode, a photodiode, and a photosensor.

18. A thin film transistor, the thin film transistor comprising: a gate electrode; an insulating layer located on the gate electrode; a semiconductor thin film located on the insulating layer and comprising an indium-selenide compound represented by Chemical Formula 1; and a source electrode and a drain electrode located at a distance from each other on the semiconductor thin film.
InₓSe_{y} [Chemical Formula 1]
in Chemical Formula 1, x is 0<x≤3, and y is 0<y≤4.

19. The thin film transistor of claim 18, wherein the semiconductor thin film comprises an indium-selenide compound of kappa(κ) phase.

20. The semiconductor thin film of claim 18, wherein the gate electrode comprises at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide and poly(3,4-ethylenedioxythiophene) polystyrene sulfonate (PEDOT:PSS).
